(19) United States
(12) Patent Application Publication
(10) Pub. No.: US 2002/0012279 A1
(43) Pub. Date: Jan. 31, 2002

(54) Low pressure operation for reduced excitation in a disc drive

(76) Inventors: James Edward Angelo, Bursnville, MN (US); Keith John Turnbull, Ritchfield, MN (US); Kurt James Korkowski, Carver, MN (US); Garry Edward Korbel, New Prague, MN (US); John William Elsing, Edina, MN (US); Zine Eddine Boutaghou, Vadnais Heights, MN (US)

Correspondence Address: Attn: Richard E. Billion, SCHWEGMAN, LUNDBERG, WOESSNER & KLUTH, P.A., P.O. Box 2938, Minneapolis, MN, 55402, US

(21) Appl. No.: 09/852,973

(22) Filed: May 10, 2001

Related U.S. Application Data
(60) Provisional application No. 60/202,891, filed on May 10, 2000.

(51) Int. Cl. G11C 7/00

(52) U.S. Cl. 365/200

(57) ABSTRACT

A disc drive includes a base, a spindle rotatably attached to the base, and at least one disc attached to the spindle. A cover is attached to the base. The cover and the base form a disc enclosure for the spindle and the disc or discs. A pump mechanism is located within the disc enclosure. The pump mechanism reduces the pressure within the disc enclosure. A valve is located in one of the cover and the base and allows a gas or fluid to move out of the disc enclosure.

### RELATED APPLICATION

This application claims the benefit of U.S. Provisional Application Serial No. 60/202,891 filed May 10, 2000 under 35 U.S.C. 119(e).

### FIELD OF THE INVENTION

The present invention relates to the field of mass storage devices. More particularly, this invention relates to an apparatus and method for reducing the pressure within a disc drive enclosure.

### BACKGROUND OF THE INVENTION

One key component of any computer system is a device to store data. Computer systems have many different places where data can be stored. One common place for storing massive amounts of data in a computer system is on a disc drive. The most basic parts of a disc drive are an information storage disc that is rotated, an actuator that moves a transducer to various locations over the disc, and electrical circuitry that is used to write and read data to and from the disc. The disc drive also includes circuitry for encoding data so that it can be successfully retrieved and written to the disc surface. A microprocessor controls most of the operations of the disc drive as well as passing the data back to the requesting computer and taking data from a requesting computer for storing to the disc.

The transducer is typically placed on a small ceramic block, also referred to as a slider, that is aerodynamically designed so that it flies over the disc. The slider is passed over the disc in a transducing relationship with the disc. Most sliders have an air-bearing surface (“ABS”) which includes rails and a cavity between the rails. When the disc rotates, air is squeezed between the rails and the disc surface causing pressure, which forces the head away from the disc. At the same time, the air rushing past the cavity or depression in the air bearing surface produces a “negative pressure” area. The “negative pressure” or suction counteracts the pressure produced at the rails. The slider is also attached to a load spring which produces a force on the slider directed toward the disc surface. The various forces equilibrate so the slider flies over the surface of the disc at a particular desired fly height. The fly height is the distance between the disc surface and the transducing head, which is typically the thickness of the air lubrication film. This film eliminates the friction and resulting wear that would occur if the transducing head and disc were in mechanical contact during disc rotation. In some disc drives, the slider passes through a layer of lubricant rather than flying over the surface of the disc.

Information representative of data is stored on the surface of the storage disc. Disc drive systems read and write information stored on tracks on storage discs. Transducers, in the form of read/write heads attached to the sliders, located on both sides of the storage disc, read and write information on the storage discs when the transducers are accurately positioned over one of the designated tracks on the surface of the storage disc. The transducer is also said to be moved to a target track. As the storage disc spins and the read/write head is accurately positioned above a target track, the read/write head can store data onto a track by writing information representative of data onto the storage disc. Similarly, reading data on a storage disc is accomplished by positioning the read/write head above a target track and reading the stored material on the storage disc. To write on or read from different tracks, the read/write head is moved radially across the tracks to a selected target track.

The methods for positioning the transducers can generally be grouped into two categories. Disc drives with linear actuators move the transducer linearly generally along a radial line to position the transducers over the various tracks on the information storage disc. Disc drives also have rotary actuators which are mounted to the base of the disc drive for accurate movement of the transducers across the tracks of the information storage disc. Rotary actuators position transducers by rotationally moving them to a specified location on an information recording disc. A rotary actuator positions the transducer quickly and precisely. For example, the rotary actuator moves the transducer at hundreds of inches per second during a long seek. The rotary actuator undergoes hundreds of G's of force when moved.

The actuator is rotatably attached to a shaft via a bearing cartridge which generally includes one or more sets of ball bearings. The shaft is attached to the base and may be attached to the top cover of the disc drive. A yoke is attached to the actuator. The voice coil is attached to the yoke at one end of the rotary actuator. The voice coil is part of a voice coil motor which is used to rotate the actuator and the attached transducer or transducers. A permanent magnet is attached to the base and cover of the disc drive. The voice coil motor which drives the rotary actuator comprises the voice coil and the permanent magnet. The voice coil is attached to the rotary actuator and the permanent magnet is fixed on the base. A yoke is generally used to attach the permanent magnet to the base and to direct the flux of the permanent magnet. Since the voice coil sandwiched between the magnet and yoke assembly is subjected to magnetic fields, electricity can be applied to the voice coil to drive it so as to position the transducers at a target track.

One problem associated with current disc drive designs is windage induced excitation or vibration. Quick and precise positioning of the transducer requires the reduction or minimization of the vibration or excitation of the structural members within the magnetic disc drive apparatus. One source of vibration or excitation of the structural members is caused by windage. Windage is air movement caused by rotating the disc or discs within a disc drive. Currently, discs are rotated at speeds of 5400 to 15,000 revolutions per minute. Higher speeds are contemplated in future drives. These higher speeds would result in more windage within a given environment in disc drive enclosure.

Another problem associated with windage and higher rotational speeds is that rotating a disc or discs within a disc drive require larger and larger amounts of power. Reducing the amount of power consumed in a disc drive is a constant design goal of disc drive manufacturers. Reducing or minimizing power consumption is absolutely critical for disc drives used in portable computers. By reducing the power consumption of one of the key components, namely the disc drive, the portable computer can run on battery power for an extra amount of time. In addition, desk top computers also seek to reduce the amount of power used. Some governments even have requirements in the specifications of the computing equipment to be purchased which limits the amount of power consumption.

What is needed is a disc drive which has is less susceptible to vibrational or excitation due to windage. This will improve settling characteristics after a seek from a first track on the disc to a target track on the disc and will improve track following operations of the disc drive. This will also improve the seeking process. In other words, there is a need for a disc drive that has less relative motion between the actuator assembly and the disc while under any type of servo control that requires corrections to be implemented with the voice coil motor. There is also a need for a disc drive which uses less power. Also needed is a disc drive device that can be assembled using current assembly techniques and which does not add cost. Further, there is a need for a solution to reduce windage and reduce power which fits within set form factors for disc drives.

### SUMMARY OF THE INVENTION

A disc drive includes a base, a spindle rotatably attached to the base, and at least one disc attached to the spindle. A cover is attached to the base. The cover and the base form a disc enclosure for the spindle and the disc or discs. A pump mechanism is located within the disc enclosure. The pump mechanism reduces the pressure within the disc enclosure. A valve is located in one of the cover and the base and allows a gas or fluid to move out of the disc enclosure. In one embodiment, the pump mechanism is integral to the spindle. The spindle includes a plurality of impeller blades adapted to direct a gas or fluid toward the valve. The valve is located in the base of the disc drive proximate the plurality of impeller blades of the spindle. In another embodiment, the impeller blades are replaced with a plurality of scales adapted to direct a gas or fluid toward the valve.

The valve includes a ball, and a seat for receiving the ball such that when the ball is received within the seat a seal is formed. The valve further includes an elastomeric member for placing a force on the ball while it is seated within the seat. The size of the elastomeric member is selected to place a select amount of force on the ball seated within the seat. In some embodiments, a spring places a force on the ball while it is seated within the seat. The spring has a force constant so that when the spring is compressed a selected distance a selected force is placed on the ball while it is seated within the seat. A portion of the ball is in fluid communication with the interior of the disc enclosure and the spring is selected so that the pressure on the ball in fluid communication with the interior of the disc enclosure produces a force allowing the ball to move away from the seat. The spring has a first end and a second end and one of these ends impinges on the ball and the other of these ends impinges on a fixed structure. In some embodiments, the fixed structure is attached to the base, and in other embodiments the fixed structure is attached to a printed circuit board. In some embodiments, the pump mechanism is made of silicon using micro-machining processes, such as a micro-electromechanical system or nano-electromechanical system.

A disc drive includes a base, a spindle rotatably attached to the base, and at least one disc attached to the spindle. The disc drive also includes a cover attached to the base. The cover and the base form a disc enclosure for the spindle and the disc or discs. The disc drive also includes a micro-machined pump mechanism for reducing the pressure within the disc enclosure, and a valve located in one of the cover and the base. The valve allows a gas or fluid to flow out of the disc enclosure. The micro-machined pump mechanism is made of silicon. The disc drive may also include a microprocessor. The micro-machined pump mechanism may be under control of the microprocessor.

Advantageously, the disc drive of the present invention is less susceptible to vibrational or excitation due to windage. Since the mechanical structures within the disc drive are less susceptible to excitation due to windage, the settling characteristics after a seek from a first track on the disc to a target track on the disc are improved. This also enhances the seeking process since there is less relative motion between the actuator assembly and the disc while under servo control. Since the excitations are lessened, the amount of servo corrections resulting from such vibration or excitation are also less. The disc drive also uses less power since the windage is less when the pressure within the disc drive is less. In other words, the low pressure environment translates into less drag on the disc or discs within the disc drive. The disc drive device that can be assembled using current assembly techniques and adds little, if any, additional cost. The present invention requires no additional sensors or pumps. In addition, the solution of the present invention for reducing windage and reducing power consumption fits within set form factors for disc drives. For example, an external pump is not needed to reduce the pressure within the disc drive. Still another advantage is that the disc drive is more reliable. The disc drive is more reliable since there is less excitation of the components, and is also more reliable since the reduced pressure operation is not dependent on external components.

### BRIEF DESCRIPTION OF THE DRAWINGS

FIG. 1 is an exploded view of a disc drive with a multiple disc stack.

FIG. 2 is a schematic representation of an embodiment of a hard disc drive incorporating an interior pump.

FIG. 3 is a bottom view of the spindle or hub assembly 133.

FIG. 4 is a representation of a ball valve used with the interior pump.

FIG. 5 is a schematic representation of another embodiment of a hard disc drive incorporating an interior pump.

FIG. 6 is a schematic representation of the embodiment of a hard disc drive incorporating an interior pump of FIG. 5 showing the disc enclosure.

FIG. 7 is a bottom view of the injection molded portion which is attached to the spindle hub assembly.

FIG. 8 is a schematic representation of yet another embodiment of a hard disc drive incorporating an interior pump.

FIG. 9 is a schematic representation of an embodiment of a hard disc drive incorporating an exterior pump.

FIG. 10 is a schematic representation of yet another embodiment of this invention.

FIG. 11 is a schematic view of a computer system.

### DESCRIPTION OF THE PREFERRED EMBODIMENT

In the following detailed description of the preferred embodiments, reference is made to the accompanying drawings which form a part hereof, and in which are shown by way of illustration specific embodiments in which the invention may be practiced. It is to be understood that other embodiments may be utilized and structural changes may be made without departing from the scope of the present invention.

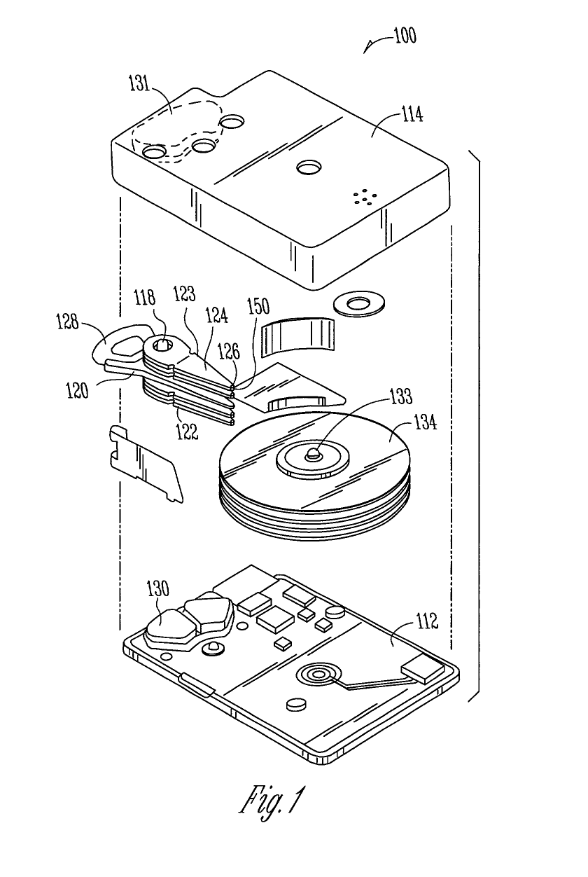

The invention described in this application is useful with all mechanical configurations of disc drives having either rotary or linear actuation. In addition, the invention is also useful in all types of disc drives including hard disc drives, zip drives, floppy disc drives and any other type of drives. FIG. 1 is an exploded view of one type of a disc drive 100 having a rotary actuator. The disc drive 100 includes a housing or base 112, and a cover 114. The base 112 and cover 114 form a disc enclosure. Rotatably attached to the base 112 on an actuator shaft 118 is an actuator assembly 120. The actuator assembly 120 includes a comb-like structure 122 having a plurality of arms 123. Attached to the separate arms 123 on the comb 122, are load beams or load springs 124. Load beams or load springs are also referred to as suspensions. Attached at the end of each load spring 124 is a slider 126 which carries a magnetic transducer 150. The slider 126 with the transducer 150 form what is many times called the head. It should be noted that many sliders have one transducer 150 and that is what is shown in the figures. It should also be noted that this invention is equally applicable to sliders having more than one transducer, such as what is referred to as an MR or magneto resistive head in which one transducer 150 is generally used for reading and another is generally used for writing. On the end of the actuator arm assembly 120 opposite the load springs 124 and the sliders 126 is a voice coil 128.

Attached within the base 112 is a first magnet 130 and a second magnet 131. As shown in FIG. 1, the second magnet 131 is associated with the cover 114. The first and second magnets 130, 131, and the voice coil 128 are the key components of a voice coil motor which applies a force to the actuator assembly 120 to rotate it about the actuator shaft 118. Also mounted to the base 112 is a spindle motor. The spindle motor includes a rotating portion called the spindle hub 133. In this particular disc drive, the spindle motor is within the hub. In FIG. 1, a number of discs 134 are attached to the spindle hub 133. In other disc drives a single disc or a different number of discs may be attached to the hub. The invention described herein is equally applicable to disc drives which have a plurality of discs as well as disc drives that have a single disc. The invention described herein is also equally applicable to disc drives with spindle motors which are within the hub 133 or under the hub.

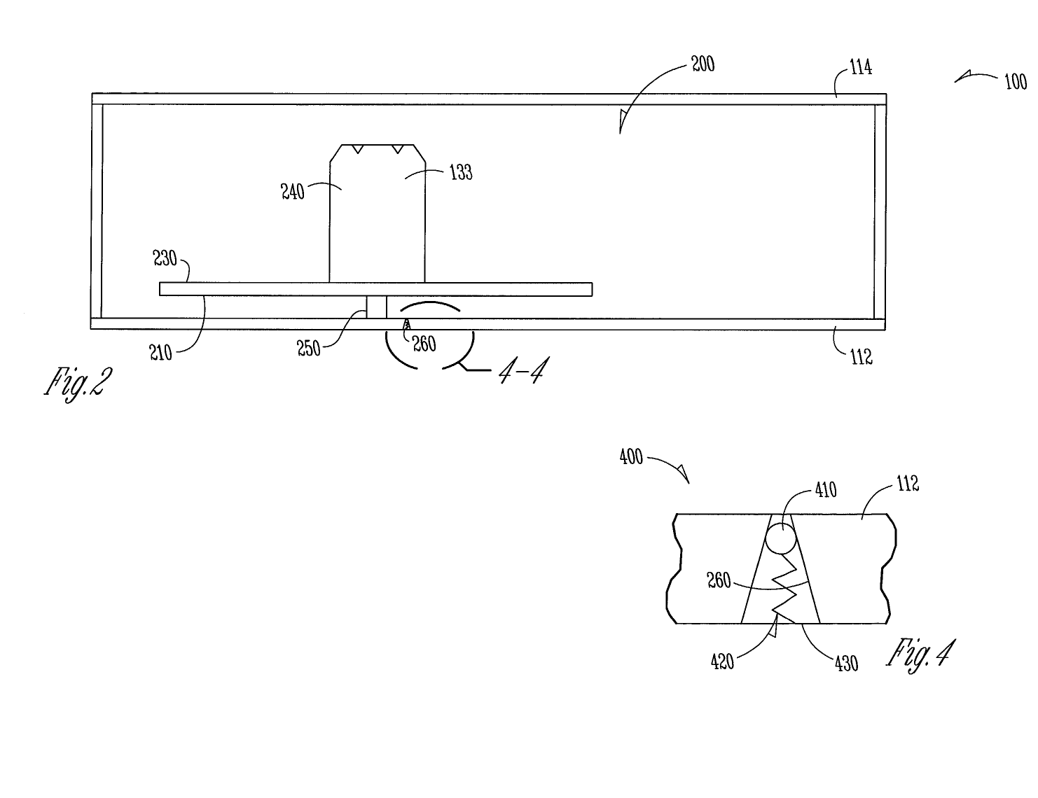

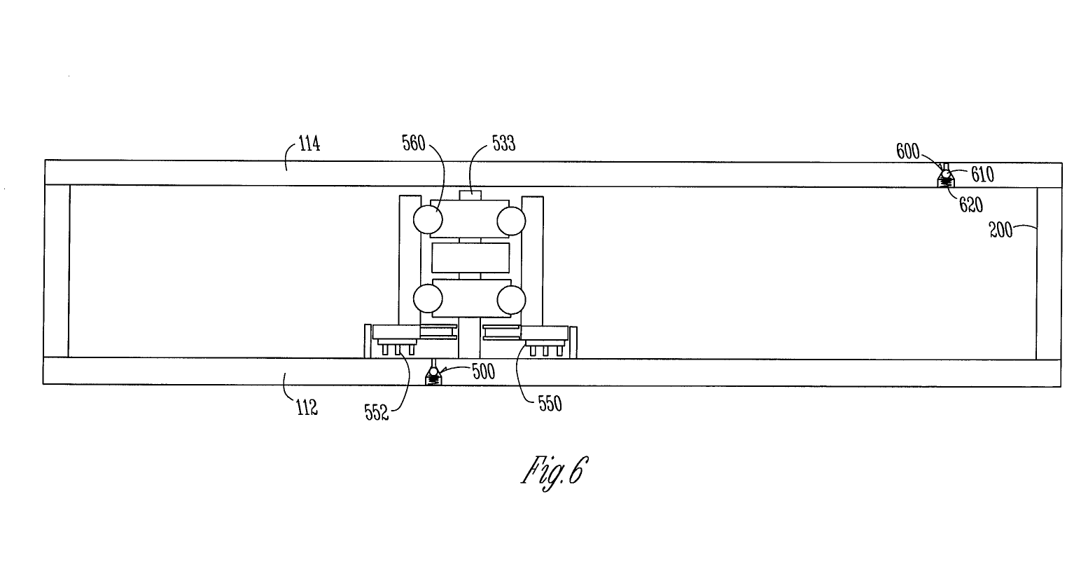

FIG. 2 is a schematic representation of an embodiment of a hard disc drive 100 incorporating an interior pump. As shown in FIG. 2, the base or deck 112, in combination with the cover 114, form a disc enclosure 200. The disc enclosure 200 is the interior environment formed inside the disc drive 100. Inside the disc drive, as shown in FIG. 2, is the spindle hub 133. The spindle hub 133 is shown without discs. Also not shown are the magnets 130, 131 and the actuator assembly 120. These components are removed for the sake of clarity but would be within a disc drive 100 incorporating this invention. The spindle hub 133 includes a surface 210 positioned near the base or deck 112 of the disc drive 100 as well as a surface 230 upon which a deck disc 134 sits (see FIGS. 1 and 5). The hub 133 also includes a central annular portion 240. The diameter of the annular portion 240 is slightly less than the inner diameter of a disc 134. As a result, the disc or discs 134 fit over the annular portion 240 (see FIG. 1). In forming a disc stack, at least one or a plurality of discs 134 are placed onto the annular portion 240 of the hub 133. The discs 134 are spaced apart from one another by ring spacers. Generally, the disc or discs are clamped to the annular portion 240 to form a disc stack with one or more discs in spaced relation with respect to one another (more clearly seen in FIGS. 1 and 5). The spindle hub 133 rotates on a pivot axis 250. The pivot axis 250 generally includes a set of bearings which allow for the smooth rotation of the spindle hub 133 and attached discs (not shown in FIG. 2). It should be noted that the spacing between the base or deck 112 and the spindle hub 133, as shown in FIG. 2, is exaggerated for the purpose of illustration. In other words, the surface 210 of the spindle hub 133 is generally more closely spaced to the base or deck 112 than illustrated in FIG. 2.

The base 112 includes an opening 260 between the disc enclosure 200 or the interior space of the disc drive 100 and the space exterior of the disc drive 100. Positioned within the opening 260 is a ball valve 400. The ball valve 400 allows for outward flow of a gas or fluid from the disc enclosure 200 or interior portion of the disc drive 100 to an area outside the disc drive 100.

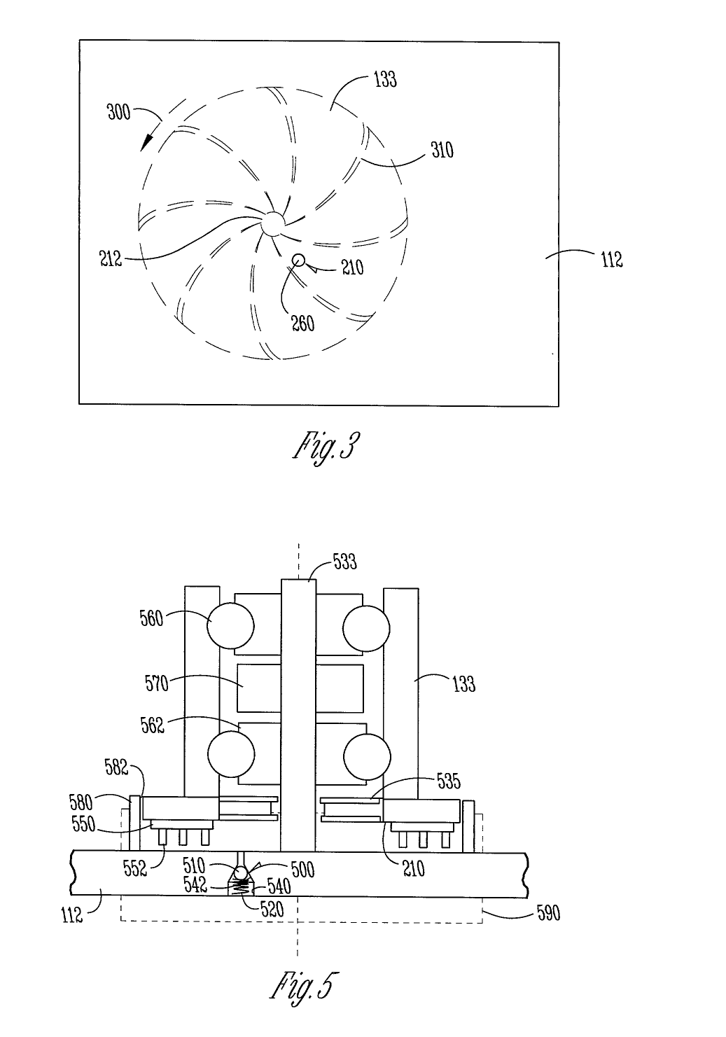

FIG. 3 is a bottom view of the disc drive 100 along line 33 in FIG. 2. FIG. 3 shows the opening 260 as well as the deck 112. FIG. 3 also shows the bottom of the spindle hub 133. Put another way, FIG. 3 shows the surface 210 of the spindle hub 133. Surface 210 is the surface of the spindle hub 133 proximate or near the base or deck 112. The direction of rotation of the spindle hub 133 is depicted by arrow 300. The surface 210 of the spindle hub 133 includes a plurality of flutes or curved surfaces 310 which are used to move air within the disc enclosure 200 toward the center of the surface 210. The center of the surface 210 is depicted by a circle carrying the reference numeral 212. The flutes 310 act as fan blades. As the spindle hub 133 rotates in direction 300, the flutes 310 move the air toward the center 212 of the surface 210 and build or form a high pressure area near the center 212 of the surface 210. The high pressure area forces the ball valve 400 to open and expel gas from the disc enclosure or interior portion of the disc drive 100 to the outside environment. In this particular embodiment, the spindle hub 133 includes an integral pump in that the flutes 310 on the bottom surface or surface 210 of the spindle hub essentially form a turbo pump to force gas from the disc enclosure to the exterior of the disc drive. Of course, it should be noted that the positioning of the flutes 310 can be changed as well as the amount of curvature of the flutes can be changed in order to accommodate specific design parameters. For example, it may not be necessary to have quite as dramatic a flute 310 if the rotational speed of the spindle hub 133 is faster than in previous applications. Furthermore, flutes 310 do not necessarily have to be used. In some instances, the surface can be provided with fish scales. It should also be noted that other designs may be used to produce a high pressure area at or near the center 212 of the surface 210 of the spindle hub.

FIG. 4 is a representation of a ball valve 400 used in conjunction with the interior pump. The opening 260 is tapered. The larger portion of the opening 260 faces the exterior of the disc drive while the smaller portion of the tapered opening 260 is positioned at or near the interior surface of the disc drive 100. The ball valve 400 includes a ball 410 and a spring 420. The ball 410 is seated within the opening 260 so that a seal is formed between the ball 410 and the opening 260. The spring 420 has one end attached to a fixed surface 430 and another end either attached to the ball 410 or impinging upon the ball 410. The spring has a force constant which is selected to place a selected amount of force on the ball 410 as seated within the opening 260. The spring and the amount of deflection is selected so that the ball valve 400 will open at or near a selected pressure within the disc drive or when the pressure at the opening 260 or proximate the ball valve 400 is at or near a selected level. When the pressure on the ball produces a force which is greater than the force placed upon the ball by the spring 420, the ball 410 unseats itself from the side of the opening 260 and allows gas from the interior portion of the disc drive 100 to pass from the interior to the exterior. When the pressure on the ball 410 produces a force less than the force produced by the spring 420, the spring 420 keeps the ball 410 seated within the opening 260. As a result, when the pressure is less than the desired pressure within the disc drive, the ball remains seated within the opening 260 and does not allow gas exterior of the disc drive to pass into the interior portion or disc enclosure 200. The ball valve 400 is self-regulating in that it opens at or near a selected pressure. The ball valve 400, therefore, acts as a one-way fluid path. Also it should be noted that the spring 420 can be attached to any fixed surface 430. For example, it is contemplated that a bar might be placed over the opening or the exterior portion of the opening 260 to which the spring 420 could attach. It is also contemplated that when the base or deck 112 is thin, an extra U-shaped portion could be added to the base 112 about the opening 260. The spring 420 could then be added to the bottom portion of the U which would form the fixed surface 430.

FIG. 5 is a schematic representation of another embodiment of a hard disc drive 100 incorporating an interior pump 550. FIG. 5 is actually only a partial showing of the disc drive 100. Specifically, FIG. 5 shows a portion of the base 112, the hub 113, the spindle shaft 533, the bearing sets 560, 562, which are used to attach the hub 133 to the spindle shaft 533, and an internal motor 57 within the hub 133. The base 112 includes a valve 500. The valve 500 includes a ball 510, a spring 520, and an opening 540 which has a tapered portion 542 into which the ball 510 is seated by the spring 520. The hub 133 includes a surface 210 which is positioned proximate or near the base 112. Attached to the surface 210 is an injection-molded ring 550 which includes impeller blades 552. The hub 133 also includes a seal 535. The seal is a positive pressure seal such as a ferrofluid seal. The base 112 also includes an annular ring structure 580. The annular ring structure produces an air gap 582 between the rotating hub 133 and the annular ring 580. The air gap is spaced or is used to control the air volume and feed for incoming air. The air gap 582 is essentially the inlet to the pump. Attached to the surface 210 of the hub 133 is a molded annular ring which includes pump fins or impellers 552. The molded annular ring 550 is formed and then attached to the surface 210 using a suitable adhesive. The ring 550 is made by injection molding. Advantageously, the ring 550 and the attached impellers 552 can be easily added to the surface 210 of the hub 133. The valve 500 is used to regulate the desired pressure within the disc drive enclosure 200. The valve 500 is essentially the outlet of the pump formed by the hub 133 and the injection molded ring attached to the bottom surface or surface 210 of the spindle 133. The disc drive may also be provided with a pressure chamber 590, which is shown in dotted lines in FIG. 5. The pressure chamber 590 is where the air is pumped out or pumped into from the valve 500.

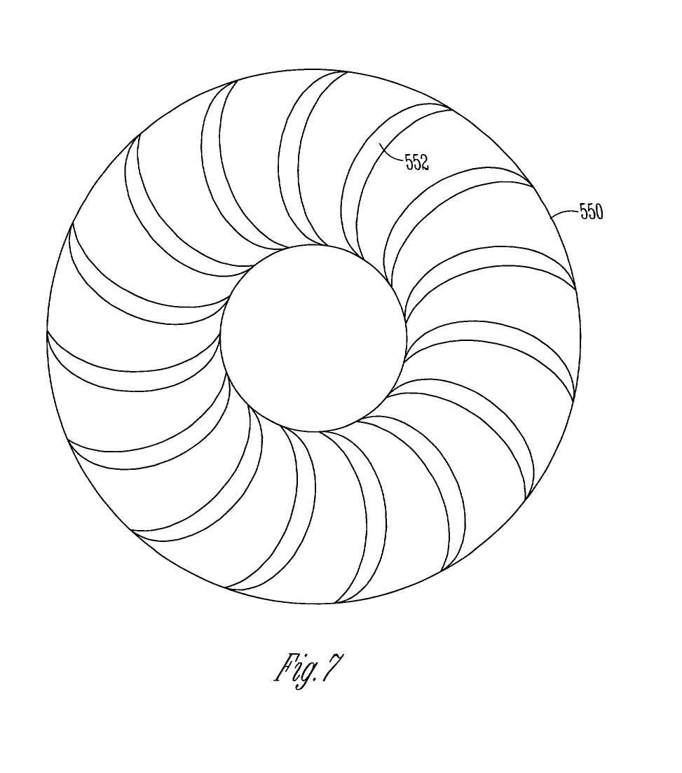

The air pump formed by the spindle 133 and the annular ring 550 with the impellers 552 is preferably attached to the base of the spindle hub 133, as shown in FIG. 5. As mentioned previously, the molded injection annular ring is attached to the outer spindle hub or surface 210 by an adhesive or other means. The outer portion of the hub and specifically the surface 210 to which the annular injection molded part 550 is attached can also be referred to as the runner of the pump that is formed. The pump impellers are designed to impart of velocity to the fluid or air relative to the vein causing a change in pressure at the inlet of the turban or pump which is formed. The valve 500, which is shown or detailed in FIG. 5 as well as FIG. 6, is needed to prevent backflow within the disc enclosure 200.

FIG. 6 is a schematic representation of the embodiment of the hard disc drive incorporating the interior pump of FIG. 5 and showing the entire disc enclosure 200. The pump formed in FIG. 5 includes the annular ring and its impellers 552 as well as the valve 500, the hub 133 and the spindle 533 upon which the hub 133 rotates. The disc enclosure is formed by the base 112 and the cover 114. The disc enclosure 200 encloses the hub 133 and attached discs or disc 134 (shown in FIG. 1). The reduction in pressure within the disc drive enclosure 200 is regulated with a pressure regulator 600, which includes a ball 610 and a spring system 620. The regulator 600 is generally integrated with an external air filter.

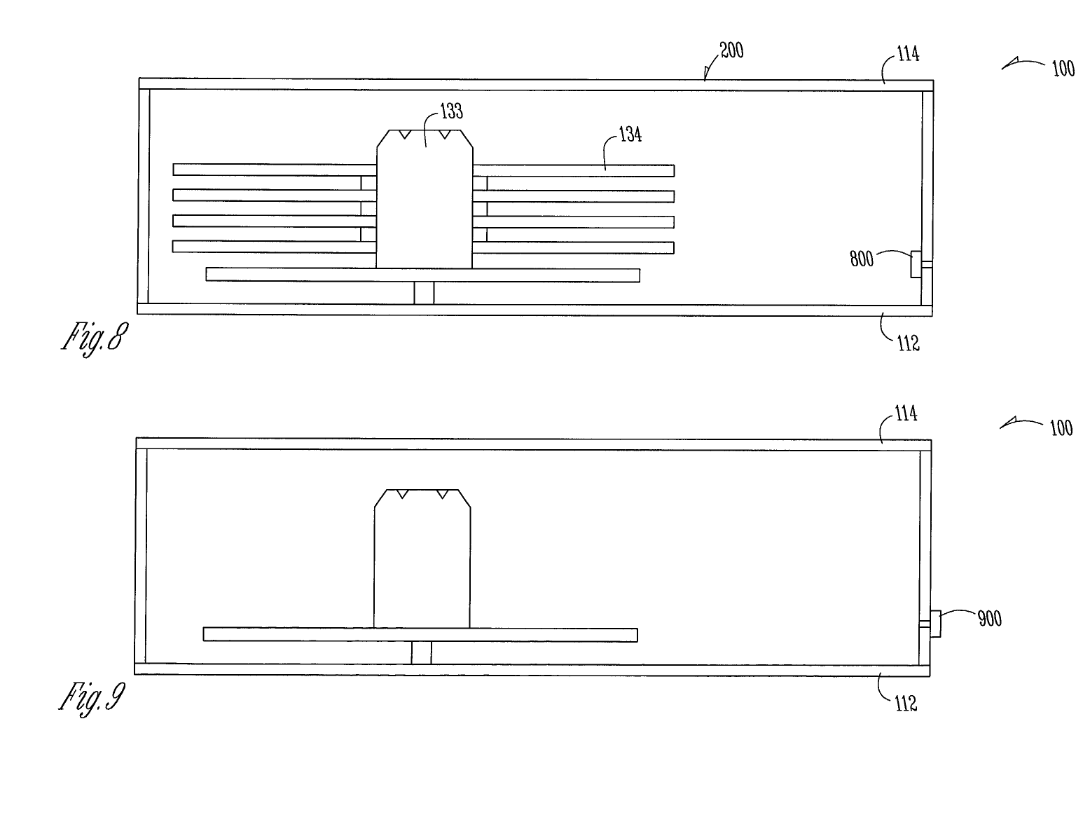

FIG. 7 is a bottom view of the injected molded portion or annular ring 500, which is attached to surface 210 of the spindle or hub assembly 133. The annular ring 550 includes impellers 552. As shown in FIG. 7, the impellers 552 are of a cup-like design. Other designs, such as a herringbone, a raleigh or other design can be used to expel the air out of the disc drive enclosure 200. As mentioned previously, the annular ring 550 may be made by injection molding. The annular ring and its impellers 552 are then attached to surface 210 of the hub assembly 133.

Advantageously, using a mold injected pump or annular ring 550 with impellers is a low-cost approach and allows use of the existing spindle hub 133. Although the spindle 133 is shown as riding on ball bearings, this approach is equally effective on a spindle hub 133, which uses a fluid bearing.

FIG. 8 is a schematic representation of another embodiment of the hard disc drive incorporating an interior pump. FIG. 5 shows a spindle hub 133 populated with a plurality of discs 134 to form a disc stack. Positioned interior to the disc enclosure is an internal pump which moves gas molecules from the interior surface of the disc drive 100 to the exterior of the disc drive. In other words, the pump 800 moves molecules of gas from the disc enclosure 200 formed by the base 112 and the cover 114 to points outside the disc drive 100. The pump 800 can be any type of pump, including pumps made from micro-electromechanical technology or from nanotechnology such as micro-machined from silicone. It should be noted that the interior pump 800 can be placed anywhere within the disc enclosure 200 including various spots on the base or deck 112 as well as various spots on the cover 114.

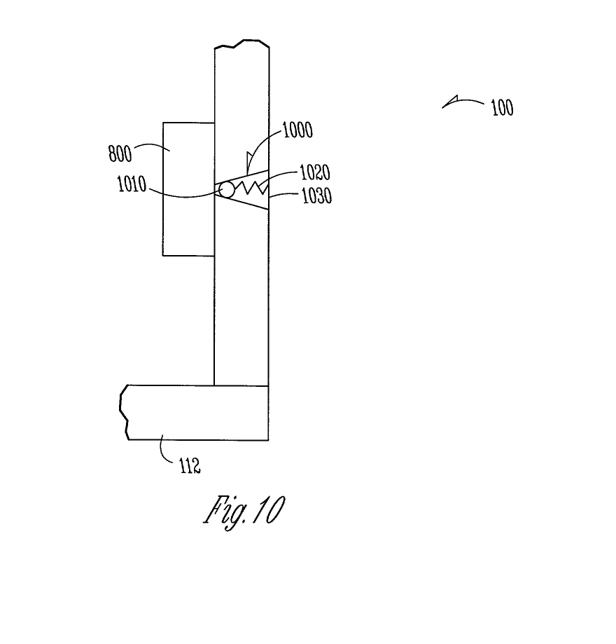

FIG. 9 is a schematic representation of an embodiment of a hard disc drive 100 incorporating an exterior pump 900. The exterior pump 900 is placed on the outside of the base 112 or on the outside of the cover 114. The external pump 900 must be small enough so as not to interfere with the form factor associated with the disc drive 100. Changing the form factor would require massive changes in the openings used for the various applications of these disc drives. In other words, the openings in bays of computers would have to be changed as well as openings used for other storage devices. Changing the form factor can be devastating to a disc drive and can actually result in nonacceptance of the disc drive in the marketplace. Therefore, it is extremely important that the end product fit within the form factor and fit within the base provided for the various applications in industry. As a result, the external pump 600 must be very, very small and must be able to be incorporated easily within the form factor. As a result, the external pump must be small and must be something such as made by nanotechnology.

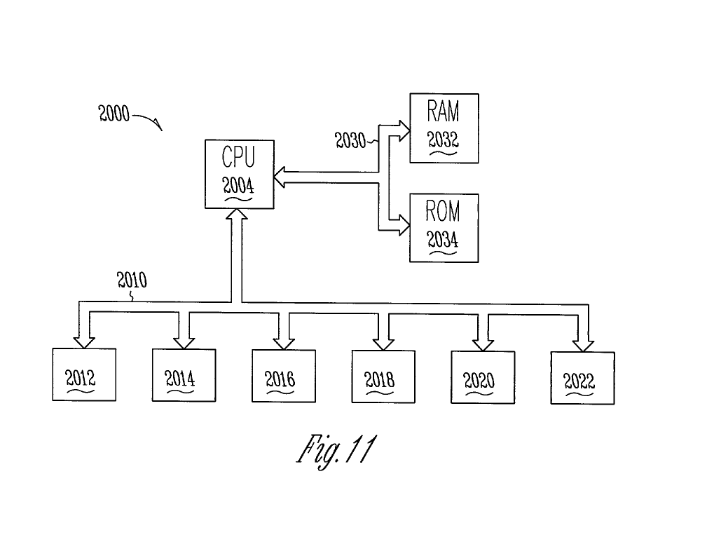

FIG. 10 shows the use of another ball valve on a thin sidewall of a base 112. The ball includes an angled or chamfered opening and a U-shaped bracket 1030. A ball 1010 fits within the opening. A spring is attached between the ball 1010 and the bracket 1030. The bracket 1030 provides the fixed surface to which the spring is attached. In the alternative, the spring 1020 may merely contact the ball 1010 rather than being connected to it. It should also be noted that the ball valve 1000 or the ball valve 400 can be located at various positions around the disc drive 100.

Advantageously, the disc drive of the present invention is less susceptible to vibrational or excitation due to windage. Since the mechanical structures within the disc drive are less susceptible to excitation due to windage, the settling characteristics after a seek from a first track on the disc to a target track on the disc are improved. This also enhances the seeking process since there is less relative motion between the actuator assembly and the disc while under servo control. Since the excitations are lessened, the amount of servo corrections resulting from such vibration or excitation are also less. The disc drive also uses less power since the windage is less when the pressure within the disc drive is less. In other words, the low pressure environment translates into less drag on the disc or discs within the disc drive. The disc drive device that can be assembled using current assembly techniques and adds little, if any, additional cost. The present invention requires no additional sensors or pumps. In addition, the solution of the present invention for reducing windage and reducing power consumption fits within set form factors for disc drives. For example, an external pump is not needed to reduce the pressure within the disc drive. Still another advantage is enhanced reliability. The disc drive is more reliable since there is less excitation of the components and also more reliable since the reduced pressure operation is not dependent on external components.

FIG. 11 is a schematic view of a computer system. Advantageously, the invention is well-suited for use in a computer system 2000. The computer system 2000 may also be called an electronic system or an information handling system and includes a central processing unit, a memory and a system bus. The information handling system includes a central processing unit 2004, a random access memory 2032, and a system bus 2030 for communicatively coupling the central processing unit 2004 and the random access memory 2032. The information handling system 2002 may also include an input/output bus 2010 and several devices peripheral devices, such as 2012, 2014, 2016, 2018, 2020, and 2022 may be attached to the input output bus 2010. Peripheral devices may include hard disc drives, magneto optical drives, floppy disc drives, monitors, keyboards and other such peripherals.

Conclusion

In conclusion, a disc drive 100 includes a base 112, a spindle 133 rotatably attached to the base 112, and at least one disc 134 attached to the spindle 133. A cover 114 is attached to the base 112. The cover and the base form a disc enclosure 200 for the spindle 133 and the disc 134 or discs 134. A pump mechanism 210 is located within the disc enclosure 200. The pump mechanism 210 reduces the pressure within the disc enclosure 200. A valve 400 is located in one of the cover 114 and the base 112 and allows a gas or fluid to move out of the disc enclosure 200. In one embodiment, the pump mechanism 210 is integral to the spindle 133. The spindle 133 includes a plurality of impeller blades 310 adapted to direct a gas or fluid toward the valve 400. The valve 400 is located in the base 112 of the disc drive 100 proximate the plurality of impeller blades 310 of the spindle 133. In another embodiment, the impeller blades 310 are replaced with a plurality of scales adapted to direct a gas or fluid toward the valve 400. The valve includes a ball 410, 1010, and a seat for receiving the ball such that when the ball 410, 1010 is received within the seat a seal is formed. The valve 400, 1000 further includes an elastomeric member 420, 1020 for placing a force on the ball 410, 1010 while it is seated within the seat. The size of the elastomeric member 420, 1010 is selected to place a select amount of force on the ball 410, 1010 seated within the seat. In some embodiments, a spring 420, 1020 places a force on the ball 410, 1010 while it is seated within the seat. The spring 420, 1020 has a force constant so that when the spring 420, 1020 is compressed a selected distance a selected force is placed on the ball 410, 1010 while it is seated within the seat. A portion of the ball 410, 1010 is in fluid communication with the interior of the disc enclosure 200 and the spring is selected so that the pressure on the ball in fluid communication with the interior of the disc enclosure 200 produces a force allowing the ball 410, 1010 to move away from the seat. The spring 420, 1020 has a first end and a second end and one of these ends impinges on the ball and the other of these ends impinges on a fixed structure. In some embodiments, the fixed structure is attached to the base 112, and in other embodiments the fixed structure is attached to a printed circuit board. In some embodiments, the pump mechanism is made of silicon.

A disc drive 100 includes a base 112, a spindle 133 rotatably attached to the base 112, and at least one disc 134 attached to the spindle 133. The disc drive 100 also includes a cover 114 attached to the base 112. The cover 114 and the base 112 form a disc enclosure 200 for the spindle 133 and the disc 134 or discs 134. The disc drive 100 also includes a micro-machined pump mechanism for reducing the pressure within the disc enclosure 200, and a valve 400, 1000 located in one of the cover 114 and the base 112. The valve 400, 1000 allows a gas or fluid to flow out of the disc enclosure 200. The micro-machined pump mechanism is made of silicon. The disc drive 100 may also include a microprocessor 2000. The micro-machined pump mechanism may be under control of the microprocessor.

Most generally, a disc drive 100 includes a base 112, a spindle 133 rotatably attached to the base 112, and at least one disc 134 attached to the spindle 133. A cover 114 is attached to the base 112. The cover 114 and the base 112 form a disc enclosure 200 for the spindle 133 and the at least one disc 134. The disc drive 100 also includes a mechanism for reducing the pressure within the disc enclosure.

It is to be understood that the above description is intended to be illustrative, and not restrictive. Many other embodiments will be apparent to those of skill in the art upon reviewing the above description. The scope of the invention should, therefore, be determined with reference to the appended claims, along with the fall scope of equivalents to which such claims are entitled.

What is claimed is:

1. A disc drive comprising:
a base;
a spindle rotatably attached to the base;
at least one disc attached to the spindle;
a cover attached to the base, the cover and the base forming a disc enclosure for the spindle and the at least one disc;
a pump mechanism located within the disc enclosure for reducing the pressure within the disc enclosure;
a valve located in one of the cover and the base for allowing a gas to move out of the disc enclosure.

2. The disc drive of claim 1 wherein the pump mechanism is integral to the spindle.

3. The disc drive of claim 1 wherein the spindle includes the pump mechanism, the spindle further including a plurality of impeller blades adapted to direct a gas toward the valve.

4. The disc drive of claim 3 wherein the valve is located in the base of the disc drive proximate the plurality of impeller blades of the spindle.

5. The disc drive of claim 1 wherein the spindle includes the pump mechanism, the spindle further including a plurality of scales adapted to direct a gas toward the valve.

6. The disc drive of claim 1 wherein the valve comprises:
a ball; and
a seat for receiving the ball such that when the ball is received within the seat a seal is formed.

7. The disc drive of claim 6 wherein the valve further comprises an elastomeric member for placing a force on the ball while it is seated within the seat.

8. The disc drive of claim 7 wherein the size of the elastomeric member is selected to place a select amount of force on the ball seated within the seat.

9. The disc drive of claim 6 wherein the valve further comprises a spring for placing a force on the ball while it is seated within the seat.

10. The disc drive of claim 9 wherein the spring has a force constant, wherein the spring is compressed a selected distance so as to place a selected force on the ball while it is seated within the seat.

11. The disc drive of claim 10 wherein the valve is in fluid communication with the interior of the disc enclosure, and wherein a portion of the ball is also in fluid communication with the interior of the disc enclosure, wherein the spring is selected so that the pressure on the ball in fluid communication with the interior of the disc enclosure produces a force allowing the ball to move away from the seat.

12. The disc drive of claim 9 wherein the spring has a first end and a second end and wherein one of the first end and the second end impinges on the ball and the other of the first end and the second end impinges on a fixed structure.

13. The disc drive of claim 12 wherein the fixed structure is attached to the base.

14. The disc drive of claim 12 wherein the fixed structure is attached to a printed circuit board.

15. The disc drive of claim 1 wherein the pump mechanism is made of silicon.

16. A disc drive comprising:
a base;
a spindle rotatably attached to the base;
at least one disc attached to the spindle;
a cover attached to the base, the cover and the base forming a disc enclosure for the spindle and the at least one disc;
a micro-machined pump mechanism for reducing the pressure within the disc enclosure;
a valve located in one of the cover and the base for allowing a gas to flow out of the disc enclosure.

17. The disc drive of claim 16 wherein the micro-machined pump mechanism is made of silicon.

18. The disc drive of claim 16 further comprising a microprocessor, wherein the micro-machined pump mechanism is under control of the microprocessor.

19. A disc drive comprising:
a base;
a spindle rotatably attached to the base;
at least one disc attached to the spindle;
a cover attached to the base, the cover and the base forming a disc enclosure for the spindle and the at least one disc;
means for reducing the pressure in the disc enclosure.

20. The disc drive of claim 19 wherein the means for reducing pressure includes a portion of the spindle.

21. The disc drive of claim 19 wherein the means for reducing pressure is formed within a portion of the spindle.

22. The disc drive of claim 19 wherein the means for reducing pressure includes impellers formed on the surface of the spindle proximate the base.

23. The disc drive of claim 19 wherein the means for reducing pressure includes an annular portion.

24. The disc drive of claim 23 wherein the annular portion includes impellers formed on a major surface of the annular portion.

25. The disc drive of claim 23 wherein the annular portion includes:
a first major surface; and
a second major surface, one of the first and second major surfaces including a plurality of impellers formed thereon, and the other of the first and second major surfaces adapted for attaching to the surface of the spindle proximate the base.

26. The disc drive of claim 23 wherein the annular portion is formed by injection molding.

27. The disc drive of claim 19 wherein the means for reducing pressure includes a pump within the disc enclosure.

28. The disc drive of claim 19 wherein the means for reducing pressure includes a pump formed from silicon outside the disc enclosure.

29. The disc drive of claim 19 wherein the means for reducing pressure includes a valve to prevent backflow of air from outside the disc enclosure.

30. The disc drive of claim 19 wherein the means for reducing pressure includes a ball valve to prevent the backflow of air from outside the disc enclosure.
